(19) United States
(12) Patent Application Publication
(10) Pub. No.: US 2026/0173533 A1
(43) Pub. Date: Jun. 18, 2026

(54) SEMICONDUCTOR DEVICE

(71) Applicant: DENSO CORPORATION, Kariya-city (JP)

(72) Inventors: Masanori MIYATA, Kariya-city (JP); Yoshihiro HORITA, Kariya-city (JP)

(21) Appl. No.: 19/531,043

(22) Filed: Feb. 5, 2026

Related U.S. Application Data
(63) Continuation of application No. PCT/JP2024/027756, filed on Aug. 2, 2024.

(30) Foreign Application Priority Data
Aug. 9, 2023 (JP) 2023-130237

(51) Int. Cl. H10D 89/10; H10D 8/00; H10D 12/00; H10D 62/10; H10D 62/60; H10D 80/20; H10D 84/00

(52) U.S. Cl. CPC H10D 89/105; H10D 8/422; H10D 12/415; H10D 12/481; H10D 62/107; H10D 62/126; H10D 62/60; H10D 84/161; H10D 80/231

(57) ABSTRACT

A semiconductor device includes a semiconductor substrate having a cell region and an outer peripheral region surrounding the cell region, a plurality of insulated gate bipolar transistor (IGBT) regions disposed in the cell region and each including an IGBT element, and a plurality of freewheeling diode (FWD) regions disposed in the cell region and each including an FWD element. The IGBT regions and the FWD regions are alternately arranged along one direction in a planar direction of the semiconductor substrate. The IGBT regions include three or more IGBT regions arranged along the one direction. When a length along the one direction is defined as a width, a width of one of the IGBT regions that is located close to a central portion in the one direction is narrower than a width of one of the IGBT regions that is located close to an end portion in the one direction.

### CROSS REFERENCE TO RELATED APPLICATIONS

The present application is a continuation application of International Patent Application No. PCT/JP2024/027756 filed on Aug. 2, 2024, which designated the U.S. and claims the benefit of priority from Japanese Patent Application No. 2023-130237 filed on Aug. 9, 2023. The entire disclosures of all of the above applications are incorporated herein by reference.

### TECHNICAL FIELD

The present disclosure relates to a semiconductor device in which an insulated gate bipolar transistor (hereinafter referred to as “IGBT”) element having an insulated gate structure and a freewheeling diode (hereinafter referred to as “FWD”) element are formed on a common semiconductor substrate.

### BACKGROUND

Conventionally, semiconductor devices have been proposed that include an IGBT region where an IGBT element is formed and an FWD region where an FWD element is formed.

### SUMMARY

A semiconductor device according to one aspect of the present disclosure includes a semiconductor substrate having a cell region and an outer peripheral region surrounding the cell region, a plurality of insulated gate bipolar transistor (IGBT) regions disposed in the cell region and each including an IGBT element, and a plurality of freewheeling diode (FWD) regions disposed in the cell region and each including an FWD element. The IGBT regions and the FWD regions are alternately arranged along one direction in a planar direction of the semiconductor substrate. The IGBT regions may include three or more IGBT regions arranged along the one direction. When a length along the one direction is defined as a width, a width of one of the IGBT regions that is located close to a central portion in the one direction may be narrower than a width of one of the IGBT regions that is located close to an end portion in the one direction.

### BRIEF DESCRIPTION OF DRAWINGS

Objects, features and advantages of the present disclosure will become apparent from the following detailed description made with reference to the accompanying drawings. In the drawings:

FIG. 1 is a plan view of a semiconductor device according to a first embodiment;

FIG. 2 is a cross-sectional view taken along line II-II in FIG. 1;

FIG. 3 is a plan view of a semiconductor device according to a comparative example;

FIG. 4 is a diagram showing a temperature distribution along line IV-IV in FIG. 1 and FIG. 3;

FIG. 5 is a diagram showing the relationship between the ratio of the maximum width to the minimum width of an IGBT region and the maximum temperature of a semiconductor device;

FIG. 6 is a plan view of the semiconductor device used for a simulation shown in FIG. 5;

FIG. 7 is a cross-sectional view of a semiconductor module;

FIG. 8 is a plan view of a semiconductor device according to a modification of the first embodiment;

FIG. 9 is a plan view of a semiconductor device according to a modification of the first embodiment;

FIG. 10 is a plan view of a semiconductor device according to a modification of the first embodiment;

FIG. 11 is a plan view of a semiconductor device according to a modification of the first embodiment;

FIG. 12 is a plan view of a semiconductor device according to a modification of the first embodiment;

FIG. 13 is a plan view of a semiconductor device according to a second embodiment;

FIG. 14 is a plan view of a semiconductor device according to a third embodiment;

FIG. 15 is a plan view of a semiconductor device according to a fourth embodiment;

FIG. 16 is a plan view of a semiconductor device according to a fifth embodiment;

FIG. 17 is a plan view of a semiconductor device according to a sixth embodiment;

FIG. 18 is a plan view of a semiconductor device according to a modification of the sixth embodiment;

FIG. 19 is a plan view of a semiconductor device according to a modification of the sixth embodiment; and

FIG. 20 is a plan view of a semiconductor device according to a seventh embodiment.

### DETAILED DESCRIPTION

Next, relevant technology is described to facilitate understanding of the following embodiments. A semiconductor device of to the relevant technology is configured to have a cell region and an outer peripheral region that surrounds the cell region, and a plurality of IGBT regions and FWD regions are formed in the cell region. In the semiconductor device, each of the IGBT regions and each of the FWD region has a planar rectangular shape with a first direction as a longitudinal direction, and the IGBT regions and FWD regions are alternately arranged along a second intersecting the first direction. In the semiconductor device, a width, which is a length along the second direction, of each of the IGBT regions is set to be equal to each other, and a width, which is a length along the second direction, of each of the FWD region is also set to be equal to each other.

In the semiconductor device described above, when IGBT elements are turned on, current flows through the IGBT regions, and when FWD elements are turned on, current flows through the FWD regions. In this case, in the semiconductor device described above, when the IGBT elements are turned on, since the widths of the IGBT regions are set to be equal, the amount of heat generated in each of the IGBT regions becomes approximately equal. Similarly, in the semiconductor device described above, when the FWD elements are turned on, since the widths of the FWD regions are set to be equal, the amount of heat generated in each of the FWD regions becomes approximately equal.

However, in the semiconductor device described above, regions located close to end portions in the second direction tend to dissipate heat more easily to a peripheral area, and therefore, the amount of heat dissipation in the regions located close to the end portions in the second direction tends to be greater than that in regions located close to a central portion in the second direction. Therefore, in the semiconductor device described, the regions located close to the central portion of the cell region in the second direction tend to have a higher temperature than the regions located close to the end portions in the second direction, and there is a possibility that the central portion may be damaged.

A semiconductor device according to one aspect of the present disclosure includes a semiconductor substrate having a cell region and an outer peripheral region that surrounds the cell region, a plurality of IGBT regions disposed in the cell region and each including an IGBT element, and a plurality of FWD regions disposed in the cell region and each including an FWD element. The plurality of IGBT regions and the plurality of FWD regions are alternately arranged along one direction in a planar direction of the semiconductor substrate. The plurality of IGBT regions include three or more IGBT regions arranged along the one direction. A length along the one direction is defined as a width. A width of one of the plurality of IGBT regions that is located close to a central portion in the one direction is narrower than a width of one of the plurality of IGBT regions that is located close to an end portion in the one direction.

According to this configuration, the width of one of the plurality of IGBT regions that is located close to the central portion in the one direction is set to be narrower than the width of one of the plurality of IGBT regions that is located close to the end portion in the one direction. Therefore, compared to a case where the widths of the plurality of IGBT regions are set to be equal to each other, it is possible to suppress the temperature of one of the plurality of IGBT regions that is located close to the central portion in the one direction from becoming excessively higher than that of one of the plurality of IGBT regions that is located close to the end portion in the one direction.

A semiconductor device according to another aspect of the present disclosure includes a semiconductor substrate having a cell region and an outer peripheral region that surrounds the cell region, a plurality of IGBT regions disposed in the cell region and each including an IGBT element, and a plurality of FWD regions disposed in the cell region and each including an FWD element. The plurality of IGBT regions and the plurality of FWD regions are alternately arranged along one direction in a planar direction of the semiconductor substrate. The plurality of FWD regions include three or more FWD regions arranged along the one direction. A length along the one direction is defined as a width. A width of one of the plurality of FWD regions that is located close to a central portion in the one direction is narrower than a width of one of the plurality of FWD regions that is located close to an end portion in the one direction.

According to this configuration, the width of one of the plurality of FWD regions that is located close to the central portion in the one direction is set to be narrower than the width of one of the plurality of FWD regions that is located close to the end portion in the one direction. Therefore, compared to a case where the widths of the plurality of FWD regions are set to be equal to each other, it is possible to suppress the temperature of one of the plurality of FWD regions that is located close to the central portion in the one direction from becoming excessively higher than that of one of the plurality of FWD regions that is located close to the end portion in the one direction.

The following describes embodiments of the present disclosure with reference to the drawings. In the following embodiments, the same or equivalent parts are denoted by the same reference numerals.

### First Embodiment

A first embodiment will be described with reference to the drawings. A semiconductor device 1 according to the present embodiment is preferably used as a power switching element used in power supply circuits such as inverters and direct current to direct current (DC/DC) converters, for example. In the present embodiment, an example will be described in which the temperature of the semiconductor device 1 becomes highest when an IGBT element is in the ON state, compared to when an FWD element is in the ON state.

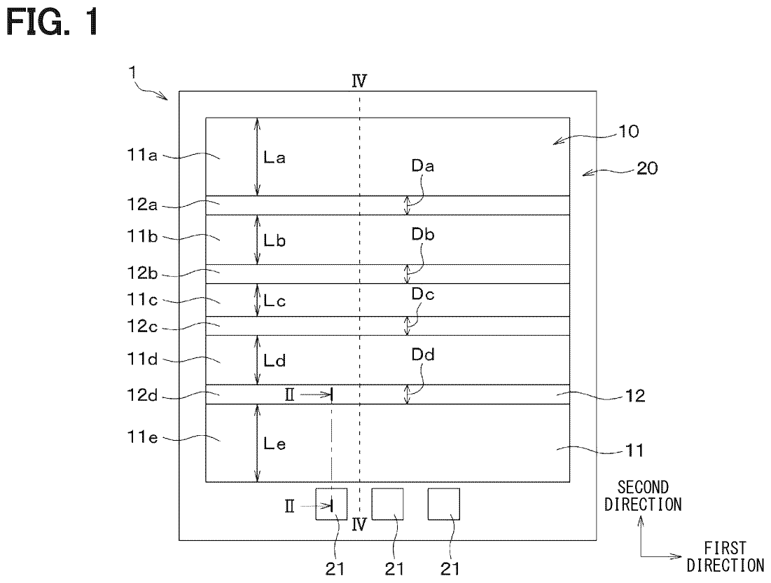

As shown in FIG. 1, the semiconductor device 1 includes a cell region 10 and an outer peripheral region 20 that surrounds the cell region 10. The cell region 10 is configured to include IGBT regions 11, in which IGBT elements are formed, and FWD regions 12, in which FWD elements are formed. That is, the semiconductor device 1 of the present embodiment is a reverse conducting (RC) IGBT in which the IGBT regions 11 and the FWD regions 12 are formed in a common semiconductor substrate 30, as will be described later. Specifically, as will be described later, in the present embodiment, portions above a collector layer 41 located on a rear surface 30b of the semiconductor substrate 30 are defined as the IGBT regions 11, and portions above a cathode layer 42 located on the rear surface 30b of the semiconductor substrate 30 are defined as the FWD regions 12.

First, a planar configuration of the semiconductor device 1 in the present embodiment will be described. In the present embodiment, the cell region 10 has a substantially rectangular planar shape. The IGBT regions 11 and the FWD regions 12 are formed so as to have portions that are alternately arranged along one direction within the cell region 10. In other words, the IGBT regions 11 and the FWD regions 12 are formed so as to have portions that are alternately arranged along one direction in a surface direction of the semiconductor substrate 30, which will be described later.

In the present embodiment, the IGBT regions 11 and the FWD regions 12 are each formed as rectangular regions having a longitudinal direction, and are alternately formed along a direction that intersects the longitudinal direction. Hereinafter, the longitudinal direction of the IGBT regions 11 and the FWD regions 12 will be referred to as a first direction, and the direction that intersects the first direction will be referred to as a second direction. In FIG. 1, the left-right direction on the page corresponds to the first direction, and the up-down direction on the page corresponds to the second direction.

It should be noted that the first direction may also be referred to as one direction in the surface direction of the semiconductor substrate 30, which will be described later, and the second direction is a direction orthogonal to the first direction, which may also be referred to as a direction along the surface direction of the semiconductor substrate 30. In addition, in the present embodiment, the IGBT regions 11 and the FWD regions 12 are alternately arranged such that the IGBT regions 11 are located at both ends in the second direction.

In the present embodiment, five IGBT regions 11 are formed along the second direction, and four FWD regions 12 are formed along the second direction. That is, in the present embodiment, an odd number of IGBT regions 11 are formed, and an even number of FWD regions 12 are formed. Furthermore, a central portion in the second direction of the cell region 10 is configured as the IGBT region 11.

Hereinafter, in the present embodiment, the five IGBT regions 11 arranged along the second direction are referred to in order along the second direction as a first IGBT region 11a, a second IGBT region 11b, a third IGBT region 11c, a fourth IGBT region 11d, and a fifth IGBT region 11e. Similarly, the four FWD regions 12 arranged along the second direction are referred to in order along the second direction as a first FWD region 12a, a second FWD region 12b, a third FWD region 12c, and a fourth FWD region 12d. In the present embodiment, the third IGBT region 11c is positioned at the central portion in the second direction of the cell region 10.

Furthermore, hereinafter, a length along the second direction is also referred to as a width. Widths La to Le of the first to fifth IGBT regions 11a to 11e and widths Da to Dd of the first to fourth FWD regions 12a to 12d are adjusted as follows.

Specifically, the IGBT regions 11 are configured such that widths of regions located close to a central portion in the second direction are narrower than widths of regions located close to end portions in the second direction. More specifically, the first to fifth IGBT regions 11a to 11e are formed such that the width Lc of the third IGBT region 11c is the narrowest, and the widths Lb and Ld of the second and fourth IGBT regions 11b and 11d and the widths La and Le of the first and fifth IGBT regions 11a and 11e become progressively wider in this order. In the present embodiment, the width Lb of the second IGBT region 11b is set to be equal to the width Ld of the fourth IGBT region 11d, and the width La of the first IGBT region 11a is set to be equal to the width Le of the fifth IGBT region 11e.

In the present embodiment, the first to fourth FWD regions 12a to 12d are formed such that their respective widths Da to Dd are equal.

In the outer peripheral region 20, a plurality of pad portions 21 are disposed. The pad portions 21 are connected to gate electrodes 35 described later, a temperature sensing element (not shown), or the like. In the present embodiment, three pad portions 21 are arranged along the first direction in a portion of the outer peripheral region 20 close to the fifth IGBT region 11e.

The above describes the planar configuration of the semiconductor device 1 in the present embodiment. Next, the cross-sectional structure of the semiconductor device 1 will be described.

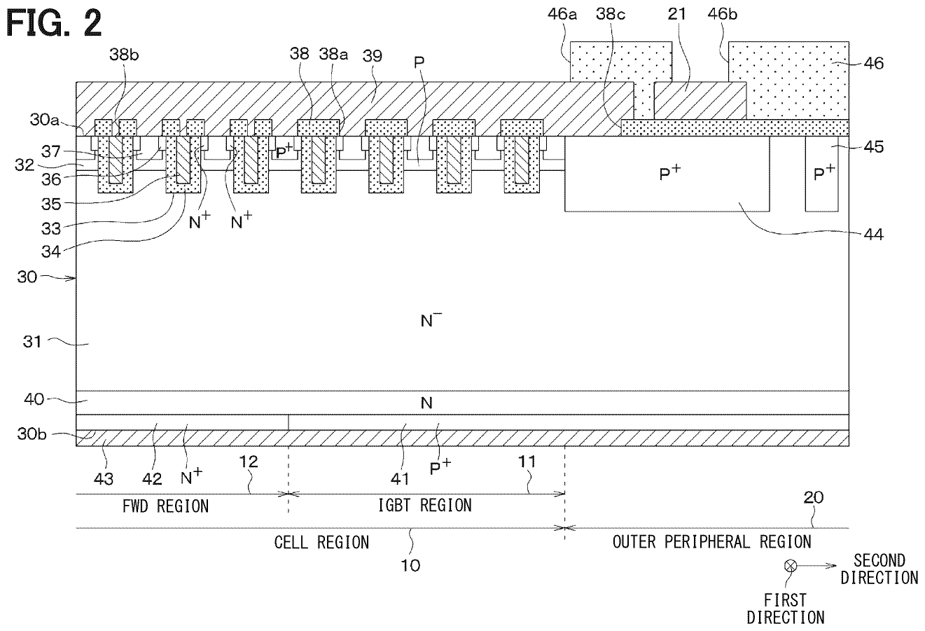

As shown in FIG. 2, the semiconductor device 1 has a semiconductor substrate 30 constituting a drift layer 31 of N⁻-type. In the present embodiment, the semiconductor substrate 30 is formed of a silicon substrate. Above the drift layer 31, a base layer 32 of P-type is disposed. In other words, the base layer 32 is formed to a front surface 30a of the semiconductor substrate 30.

A plurality of trenches 33 are provided in the semiconductor substrate 30 from the front surface 30a so as to penetrate through the base layer 32 and reach the drift layer 31. Accordingly, the base layer 32 is divided into multiple pieces by the trenches 33. In the present embodiment, the trenches 33 are formed in each of the IGBT regions 11 and the FWD regions 12. In the present embodiment, the trenches 33 are formed in a stripe pattern with the first direction as the longitudinal direction.

Each of the trenches 33 is embedded with a gate insulating film 34 and a gate electrode 35. The gate insulating film 34 covers a wall surface of each of the trenches 33. The gate electrode 35 is formed of polysilicon or the like and is formed on the gate insulating film 34. Accordingly, a trench gate structure is formed.

The gate electrodes 35 disposed in the trenches 33 formed in the IGBT regions 11 are connected, via gate wiring (not shown), to one of the pad portions 21 shown in FIG. 1, so that a predetermined gate voltage can be applied. In addition, the gate electrodes 35 disposed in the trenches 33 formed in the FWD regions 12 are electrically connected to an upper electrode 39, which will be described later. In other words, the gate electrodes 35 in the FWD regions 12 are maintained at a predetermined potential.

In a surface region of the base layer 32 in the IGBT regions 11 and the FWD regions 12 (that is, a region of the semiconductor substrate 30 close to the front surface 30a), emitter regions 36 of N⁺-type having a higher impurity concentration than the drift layer 31 are formed. In addition, in the surface region of the base layer 32 in the IGBT regions 11 and the FWD regions 12, contact regions 37 of P⁺-type having a higher impurity concentration than the base layer 32 are formed. The emitter regions 36 are formed so as to terminate in the base layer 32 and to be in contact with side surfaces of the trenches 33, respectively. Furthermore, the contact regions 37 are formed so as to terminate in the base layer 32, similarly to the emitter regions 36.

More specifically, each of the emitter regions 36 is formed in a bar shape in a region between the trenches 33, extends along the longitudinal direction of the trenches 33 so as to be in contact with the side surface of one of the trenches 33, and terminates at a position shallower than tip ends of the trenches 33. In addition, each of the contact regions 37 is formed in a bar shape extending along the longitudinal direction of the trenches 33 (that is, along the emitter regions 36), and is sandwiched between two emitter regions 36.

In the present embodiment, a portion of the wall surface of each of the trenches 33 located between each of the emitter regions 36 and the drift layer 31 serves as a surface of the base layer 32 positioned between each of the emitter regions 36 and the drift layer 31. In addition, each of the contact regions 37 in the present embodiment is formed deeper than the emitter regions 36 with reference to the front surface 30a of the semiconductor substrate 30.

An interlayer insulating film 38 made of borophosphosilicate glass (BPSG) or the like is formed on the front surface 30a of the semiconductor substrate 30. An upper electrode 39 is formed on the interlayer insulating film 38 so as to be electrically connected to the emitter regions 36 and the contact regions 37 (that is, the base layer 32) through contact holes 38a provided in the interlayer insulating film 38. In other words, the upper electrode 39 is disposed on the interlayer insulating film 38 to function as an emitter electrode in the IGBT regions 11 and function as an anode electrode in the FWD regions 12.

In the present embodiment, contact holes 38b are formed in the interlayer insulating film 38 in the FWD regions 12 to expose the gate electrodes 35. Then, the upper electrode 39 is also connected to the gate electrodes 35 through the contact holes 38b. As a result, the gate electrodes 35 formed in the FWD regions 12 are maintained at the same potential as the upper electrode 39.

On a side of the drift layer 31 opposite to the base layer 32 (that is, on a side of the drift layer 31 close to the rear surface 30b of the semiconductor substrate 30), a field stop layer (hereinafter referred to as an FS layer) 40 of N-type having a higher impurity concentration than the drift layer 31 is formed.

Then, in the IGBT regions 11, a collector layer 41 of P⁺⁻type is formed on the side opposite to the drift layer 31 across the FS layer 40, and in the FWD regions 12, a cathode layer 42 of N⁺-type is formed on the side opposite to the drift layer 31 across the FS layer 40. In other words, the IGBT regions 11 and the FWD regions 12 are distinguished by whether the layer formed on the rear surface 30b of the semiconductor substrate 30 is the collector layer 41 or the cathode layer 42. In the outer peripheral region 20, the collector layer 41 is formed on the side opposite to the drift layer 31 across the FS layer 40.

On the side opposite to the drift layer 31, across the collector layer 41 and the cathode layer 42 (that is, on the rear surface 30b of the semiconductor substrate 30), a lower electrode 43 electrically connected to the collector layer 41 and the cathode layer 42 is formed. In other words, the lower electrode 43 is formed so as to function as a collector electrode in the IGBT regions 11 and as a cathode electrode in the FWD regions 12. Furthermore, the lower electrode 43 is also connected to the collector layer 41 in the outer peripheral region 20.

With the configuration described above, in the FWD regions 12, the FWD elements are formed by PN junction with the base layer 32 and the contact regions 37 as anodes and the drift layer 31, the FS layer 40, and the cathode layer 42 as cathodes.

The outer peripheral region 20 has a drift layer 31 similar to that of the cell region 10. Furthermore, a deep layer 44 of P⁺-type having a higher impurity concentration than the base layer 32 is formed in a surface region of the drift layer 31 in order to suppress electric field concentration in the cell region 10. The deep layer 44 is formed at a boundary with the cell region 10, is connected to the base layer 32, and serves to suppress electric field concentration in the cell region 10. In the present embodiment, the deep layer 44 is formed deeper than the base layer 32 and is shaped in a frame surrounding the cell region 10. In addition, in the present embodiment, in order to suppress electric field concentration at corners of a planar shape of the deep layer 44, portions of the deep layer 44 located at the corners are formed with an R shape having a rounded curvature. In other words, the deep layer 44 has a rectangular frame with rounded corners or a circular frame in plan view.

In addition, in the outer peripheral region 20, a guard ring 45 is formed in the surface region of the drift layer 31 so as to surround the deep layer 44. In practice, a plurality of guard rings 45 are formed, each having an annular structure that surrounds the cell region 10. In other words, the guard rings 45 are formed so as to constitute a multi-ring structure. It should be noted that, similar to the deep layer 44, each of the guard rings 45 also has a planar shape such as a rectangular frame with rounded corners or a circular frame.

The pad portions 21 arranged in the outer peripheral region 20 are disposed on the deep layer 44.

In addition, in the outer peripheral region 20, an interlayer insulating film 38 is formed on the front surface 30a of the semiconductor substrate 30 as in the cell region 10. Then, a contact hole 38c is formed in the interlayer insulating film 38 to expose the deep layer 44, and the upper electrode 39 is also connected to the deep layer 44 through the contact hole 38c.

In addition, above the front surface 30a of the semiconductor substrate 30, a protective film 46 made of polyimide or the like is formed. The protective film 46 is provided with a contact hole 46a to expose the upper electrode 39 in the cell region 10, and also with contact holes 46b to expose the pad portions 21 in the outer peripheral region 20. It should be noted that the contact hole 46a of the present embodiment is formed so as to expose the entire cell region 10, and the contact hole 46a is formed to have a substantially rectangular planar shape corresponding to the cell region 10.

The configuration of the semiconductor device according to the present embodiment has been described above. In the present embodiment, the N-type, the N⁺-type, and the N⁻-type correspond to a first conductive type, and the P-type and P⁺-type correspond to a second conductive type. In addition, in the present embodiment, with the semiconductor device 1 configured as described above, the semiconductor substrate 30 has a structure that includes the collector layer 41, the cathode layer 42, the drift layer 31, the base layer 32, the emitter regions 36, the contact regions 37, and the like.

Next, the operation of the semiconductor device 1 described above will be explained, along with a more detailed description of the configuration of the semiconductor device 1.

In the semiconductor device 1 as described above, when a voltage higher than that of the upper electrode 39 is applied to the lower electrode 43, the PN junction formed between the base layer 32 and the drift layer 31 enters a reverse conduction state, thereby forming a depletion layer. Then, when a low-level gate voltage (for example, 0 V) that is less than a threshold voltage Vth of the insulated gate structure is applied to the gate electrodes 35, no current flows between the upper electrode 39 and the lower electrode 43.

To turn the IGBT elements on, a high-level gate voltage equal to or greater than the threshold voltage Vth of the insulated gate structure is applied to the gate electrodes 35 of the IGBT regions 11, while a voltage higher than that of the upper electrode 39 is applied to the lower electrode 43. As a result, in the IGBT regions 11, inversion layers are formed in portions of the base layer 32 that are in contact with the trenches 33 where the gate electrodes 35 are disposed. Then, in the IGBT elements, electrons are supplied from the emitter regions 36 to the drift layer 31 via the inversion layers, thereby holes are supplied from the collector layer 41 to the drift layer 31. As a result of this conductivity modulation, the resistance value of the drift layer 31 decreases. As a result, current flows between the upper electrode 39 and the lower electrode 43 in the IGBT elements.

At this time, in the IGBT regions 11 of the present embodiment, the widths of the regions located close to the central portion in the second direction are set to be narrower than the widths of the regions located close to the end portions in the second direction. Therefore, in the IGBT regions 11, the regions located close to the central portion in the second direction carry a smaller amount of current and generate less heat than the regions located close to the end portions in the second direction. In other words, in the IGBT regions 11, the regions located close to the central portion in the second direction, which are less capable of dissipating heat, are made less likely to generate heat than the regions located close to the end portions in the second direction, which are more capable of dissipating heat. Accordingly, when the IGBT elements are in the ON state, it is possible to suppress the regions located close to the central portion in the second direction of the cell region 10 from becoming high in temperature.

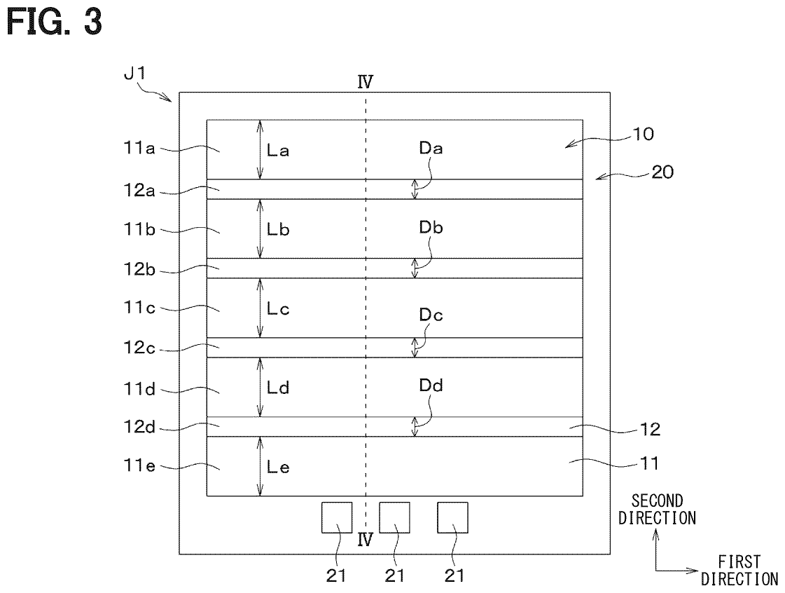

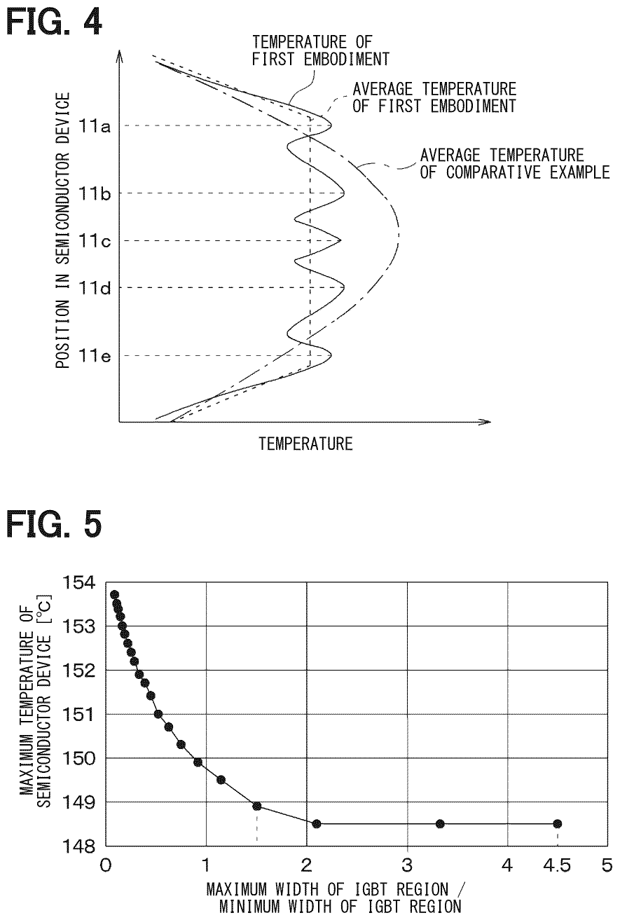

Here, as shown in FIG. 3, a semiconductor device in which the widths La to Le of the first to fifth IGBT regions 11a to 11e are set to be equal is referred to as a semiconductor device J1 of a comparative example. Then, according to the studies conducted by the present inventors, when the IGBT elements were turned on, the temperatures of the semiconductor device 1 of the present embodiment and the semiconductor device J1 of the comparative example showed the results shown in FIG. 4. It should be noted that the temperatures in FIG. 4 indicate the temperatures along cross sections IV-IV in FIGS. 1 and 3. Additionally, 11a to 11e in FIG. 4 indicate the centers in the second direction of the first to fifth IGBT regions 11a to 11e, respectively.

As shown in FIG. 4, in the semiconductor device J1 of the comparative example, since the widths La to Le of the first to fifth IGBT regions 11a to 11e are set to be equal, it is confirmed that the temperature becomes higher at the central portion in the second direction. Specifically, the temperature of the third IGBT region 11c becomes extremely high.

In contrast, in the semiconductor device 1 of the present embodiment, the widths of the regions located close to the central portion in the second direction are set to be narrower than the widths of the regions located close to the end portions in the second direction. In other words, in the semiconductor device 1 of the present embodiment, the width Lc of the third IGBT region 11c is set to be narrower than those of the first, second, fourth, and fifth IGBT regions 11a, 11b, 11d, and 11e. Therefore, it is possible to suppress the temperature of the third IGBT region 11c, which is the most difficult to dissipate heat, from becoming excessively high.

Furthermore, in the present embodiment, as shown in FIG. 4, the widths La to Le of the first to fifth IGBT regions 11a to 11e are adjusted so that the average temperatures of the first to fifth IGBT regions 11a to 11e become approximately equal. Specifically, in the semiconductor device 1, the regions located closer to the end portions in the second direction exhibit higher heat dissipation. Therefore, the first to fifth IGBT regions 11a to 11e in the present embodiment are formed such that the width Lc of the third IGBT region 11c is the narrowest, and the widths Lb and Ld of the second and fourth IGBT regions 11b and 11d and the widths La and Le of the first and fifth IGBT regions 11a and 11e become progressively wider in this order. As a result, it is possible to suppress variations in the lifetime and other characteristics of the gate insulating film 34 among the first to fifth IGBT regions 11a to 11e.

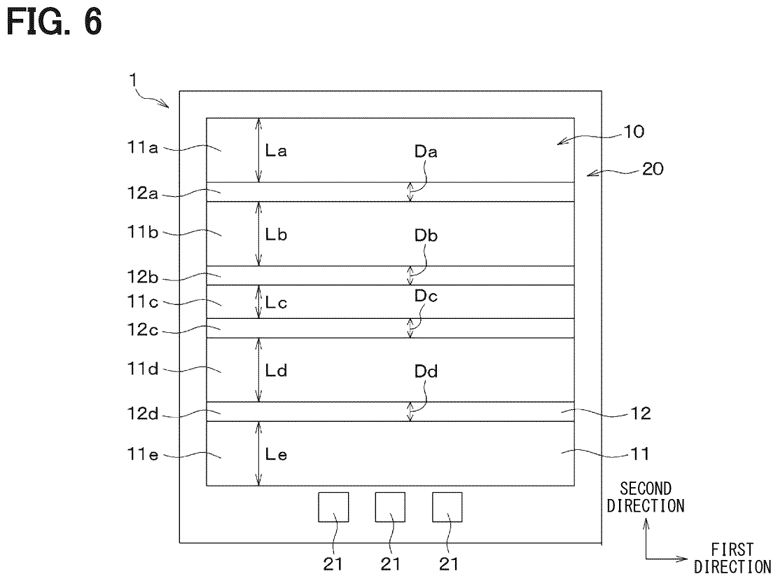

In addition, the present inventors further investigated the width of the IGBT region 11 and obtained the results shown in FIG. 5. FIG. 5 shows the results in the case where, as illustrated in FIG. 6, the width Lc of the third IGBT region 11c is set to be the narrowest, while the widths La, Lb, Ld, and Le of the first, second, fourth, and fifth IGBT regions 11a, 11b, 11d, and 11e are set to be equal. In addition, the maximum temperature of the semiconductor device 1 in FIG. 5 refers to the temperature of the third IGBT region 11c when the IGBT elements are in the ON state.

As shown in FIG. 5, it is confirmed that, within the range where the ratio of the maximum width to the minimum width of the IGBT regions 11 (hereinafter simply referred to as the “IGBT region width ratio”) is less than 1.5, the maximum temperature of the semiconductor device 1 decreases sharply as the IGBT region width ratio increases. However, it is confirmed that the maximum temperature of the semiconductor device 1 remains almost unchanged when the IGBT region width ratio is in the range of 1.5 to 4.5. Accordingly, it is preferable that the IGBT region width ratio is set within the range of 1.5 to 4.5. As a result, the temperature of the third IGBT region 11c can be sufficiently lowered.

When the IGBT elements are turned to the OFF state and the FWD elements are turned to the ON state (that is, the FWD elements are operated as diodes), the voltages to be applied to the upper electrode 39 and the lower electrode 43 are switched, and a voltage higher than that applied to the lower electrode 43 is applied to the upper electrode 39. As a result, holes are supplied to the base layer 32 and electrons are supplied to the cathode layer 42, causing the FWD elements to operate as the diodes.

The semiconductor device 1 described above is used, for example, to constitute a semiconductor module for driving a motor as a load.

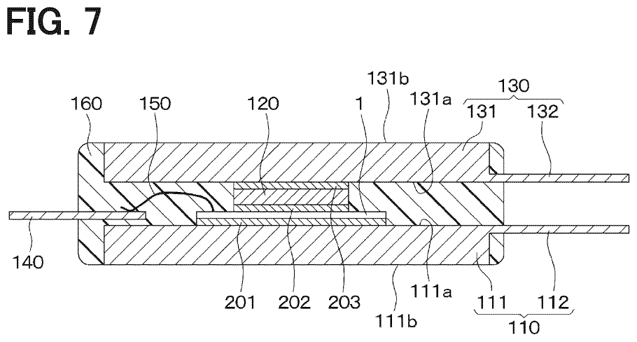

For example, as shown in FIG. 7, the semiconductor module is configured to include a first support member 110, the semiconductor device 1, a terminal 120, a second support member 130, a control terminal portion 140, a sealing member 160, and the like.

The first support member 110 is formed of a lead frame made of copper, iron, or an alloy thereof, for example. In the present embodiment, the first support member 110 includes a first mounting portion 111 having a front surface 111a and a rear surface 111b opposite to the front surface 111a, and a first connection terminal portion 112 connected to the first mounting portion 111. It should be noted that the first connection terminal portion 112 extends along a planar direction of the front surface 111a of the first mounting portion 111. In the present embodiment, the first connection terminal portion 112 is integrated with the first mounting portion 111. In addition, in the present embodiment, the first connection terminal portion 112 extends in a direction opposite to the control terminal portion 140, which will be described later.

The semiconductor device 1 is configured as described above and is disposed above the front surface 111a of the first mounting portion 111 via a first bonding member 201 made of solder or the like, in a state where the lower electrode 43 faces the first mounting portion 111.

The terminal 120 is made of, for example, copper, iron, or alloys thereof, and has a shape corresponding to the planar shape of the upper electrode 39 exposed from the protective film 46 in the semiconductor device 1. In the present embodiment, since the opening portion of the contact hole 46a formed in the protective film 46 is substantially rectangular, the terminal 120 is also substantially rectangular in plan view. The terminal 120 is disposed above the upper electrode 39 of the semiconductor device 1 via a second bonding member 202 made of solder or the like.

Specifically, in the semiconductor device 1, a plating layer for improving the wettability with solder, which constitutes the second bonding member 202, is formed on the portion exposed through the contact hole 46a of the protective film 46. The terminal 120 is disposed above the plating layer via the second bonding member 202.

The second support member 130 is formed of a lead frame similar to the first support member 110 or the like, and includes a second mounting portion 131 having a front surface 131a and a rear surface 131b opposite to the front surface 131a, and a second connection terminal portion 132 connected to the second mounting portion 131.

The second support member 130 is connected to the terminal 120 via a third bonding member 203 made of solder or the like, with the front surface 131a of the second mounting portion 131 being joined to the terminal 120 through the third bonding member 203. That is, the first support member 110 and the second support member 130 are arranged so as to face each other with the semiconductor device 1 interposed therebetween. The second connection terminal portion 132 extends along a planar direction of the front surface 131a of the second mounting portion 131. In the present embodiment, the second connection terminal portion 132 extends in the same direction as the first connection terminal portion 112. In addition, in the present embodiment, the second connection terminal portion 132 is integrated with the second mounting portion 131.

The control terminal portion 140 is connected to the pad portions 21 formed on the semiconductor device 1 via bonding wires 150. In the present embodiment, the control terminal portion 140 corresponds to an external terminal portion.

The sealing member 160 is composed of a molding resin, potting resin, or the like, and is formed so as to seal the first support member 110, the semiconductor device 1, the second support member 130, the control terminal portion 140, and the like. Specifically, the sealing member 160 is formed so that the rear surface 111b of the first mounting portion 111 of the first support member 110, the rear surface 131b of the second mounting portion 131 of the second support member 130, and parts of each of the terminal portions 112, 132, and 140 are exposed.

According to the present embodiment, the width of the region of the IGBT region 11 located close to the central portion in the second direction is set to be narrower than the width of the regions located close to the end portions in the second direction. Therefore, compared to the case where the widths of the IGBT regions 11 are set to be equal, it is possible to suppress the temperature of the IGBT region 11 located close to the central portion in the second direction from becoming excessively higher than the temperature of the IGBT regions 11 located close to the end portions in the second direction. Therefore, for example, compared to the semiconductor device J1 of the comparative example, it is possible to increase the amount of current that can be passed until the maximum temperature becomes the same, thereby improving application selectivity.

In the present embodiment, among the first to fifth IGBT regions 11a to 11e, the width Lc of the third IGBT region 11c, which is located at the central portion in the second direction, is set to be the narrowest. Therefore, it is possible to suppress the temperature of the IGBT region 11 located at the central portion in the second direction from becoming excessively high. It should be noted that, with such a configuration, if X IGBT regions 11, where X is an odd number equal to or greater than three, are arranged along the second direction, it can be said that the width of the region located at the {(X+1)/2}th position along the second direction is set to be the narrowest.

In the present embodiment, by setting the IGBT region width ratio to between 1.5 and 4.5, the maximum temperature of the semiconductor device 1 can be sufficiently lowered.

### Modifications of the First Embodiment

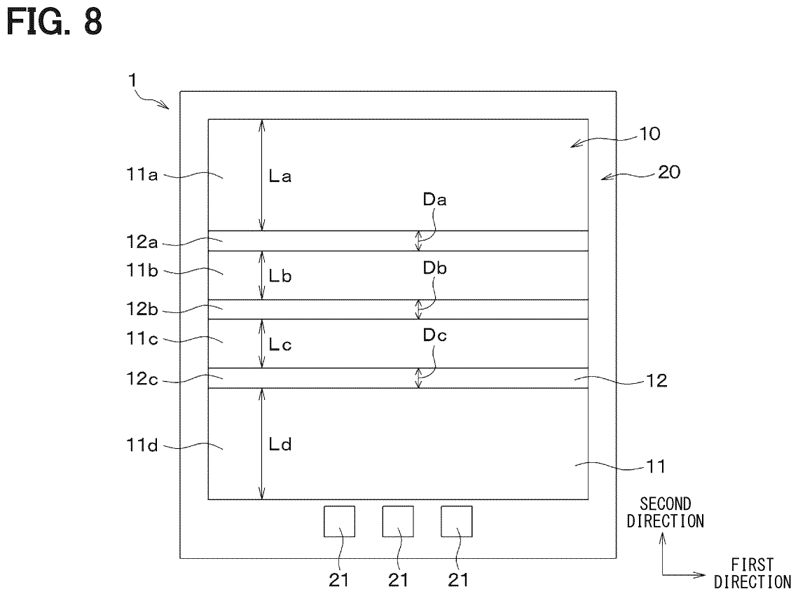

Modifications of the first embodiment will be described below. In the first embodiment, the number and arrangement of the IGBT regions 11 and the FWD regions 12 can be appropriately modified. For example, as shown in FIG. 8, four IGBT regions 11 (first to fourth IGBT regions 11a to 11d) may be formed along the second direction, and three FWD regions 12 (first to third FWD regions 12a to 12c) may be formed as well. That is, in this example, an even number of IGBT regions 11 are formed, and an odd number of FWD regions 12 are formed. In addition, an FWD region 12 is disposed at the central portion of the cell region 10 in the second direction.

Furthermore, in the IGBT regions 11, the widths of the regions located close to the central portion in the second direction are set to be narrower than the width of the regions located close to the end portions in the second direction. Specifically, among the first to fourth IGBT regions 11a to 11d, the widths Lb and Lc of the second and third IGBT regions 11b and 11c are set to be narrower than the widths La and Ld of the first and fourth IGBT regions 11a and 11d. As described above, the first embodiment can also be applied in cases where the number of IGBT regions 11 along the second direction is an even number of four or more. In such a configuration, assuming that X IGBT regions 11, where X is an even number of four or more, are arranged along the second direction, it can be said that the widths of the region positioned at the (X/2)th and the region positioned at the {(X/2)+1}th along the second direction are the narrowest.

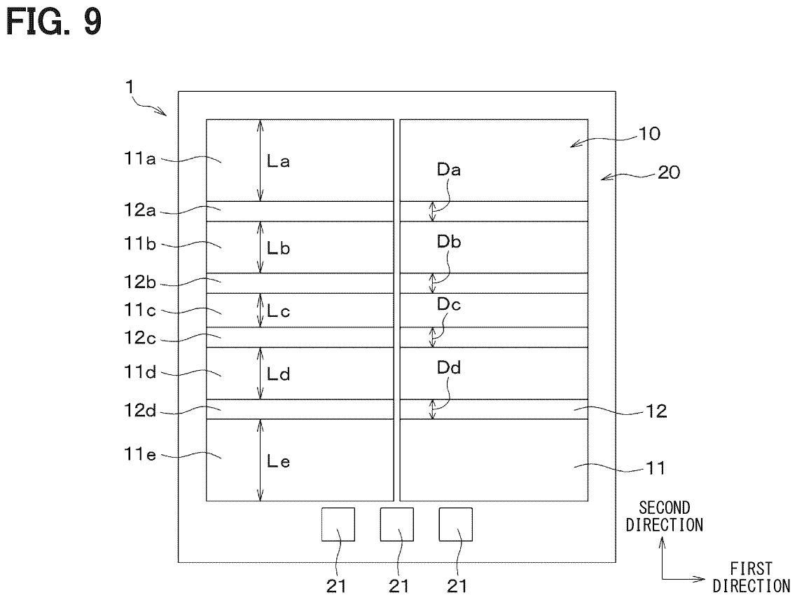

Furthermore, in the first embodiment, as shown in FIG. 9, the semiconductor device 1 may have the IGBT regions 11 and the FWD regions 12 divided in the first direction. In this case, it is possible to arrange a gate liner or the like connected to the gate electrodes 35 in the divided portions, or to arrange a temperature sensor or the like.

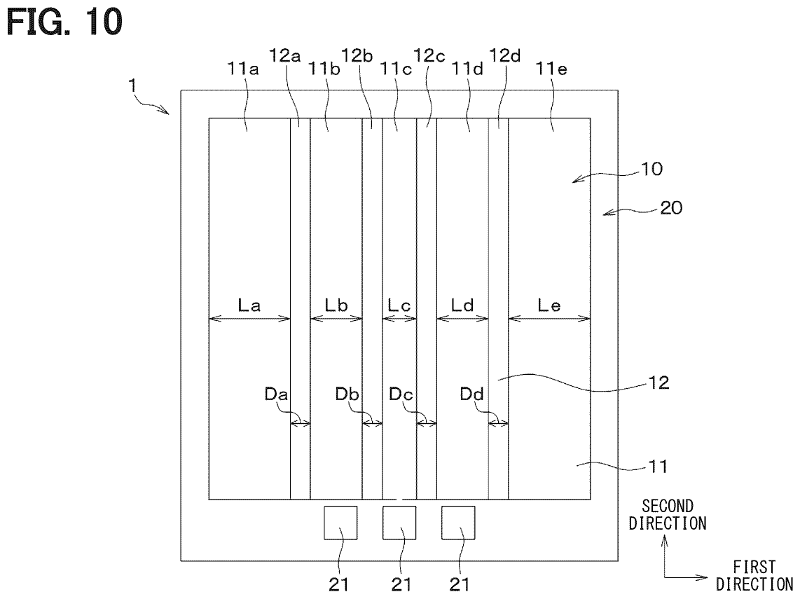

Furthermore, as shown in FIG. 10, the semiconductor device 1 may be configured such that the IGBT regions 11 and the FWD regions 12 are extended in the second direction as the longitudinal direction and are alternately arranged along the first direction. In this case, the first direction corresponds to one direction along the planar direction of the semiconductor substrate 30.

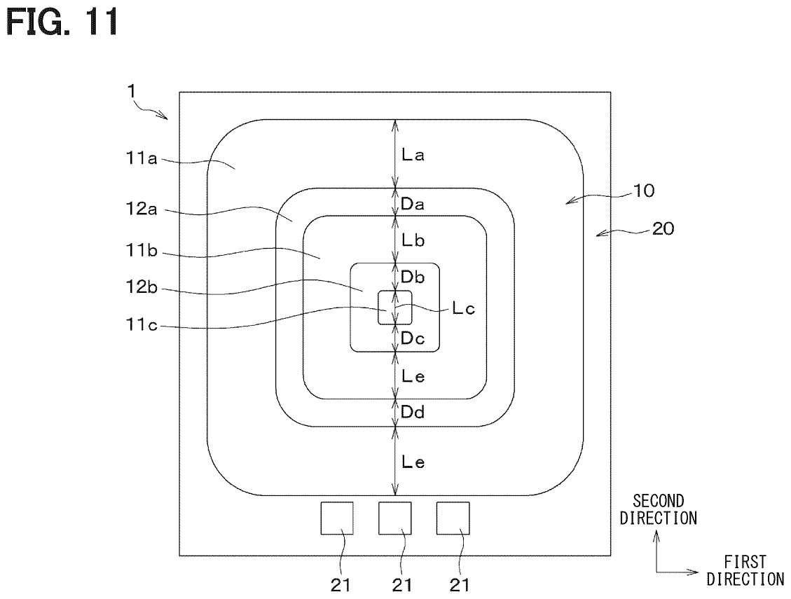

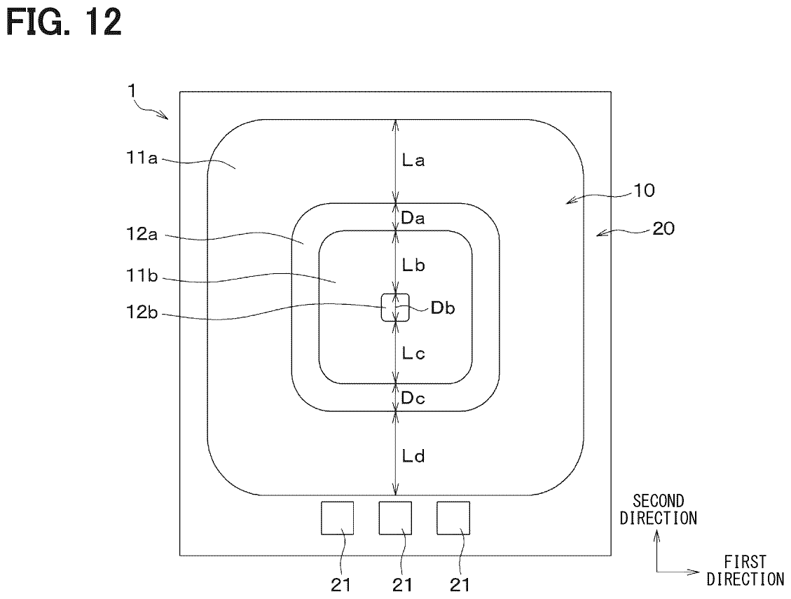

In addition, as shown in FIG. 11 and FIG. 12, the semiconductor device 1 may have the IGBT regions 11 and the FWD regions 12 alternately formed in a concentric frame shape. In this case, if the first direction and the second direction are defined as in the first embodiment, it can be said that the IGBT regions 11 and the FWD regions 12 are alternately formed along the first and second directions.

For example, in FIG. 11, three IGBT regions 11, that is, the first to third IGBT regions 11a to 11c, and two FWD regions 12, that is, the first and second FWD regions 12a and 12b, are formed in a concentric frame shape. Then, in FIG. 11, it can be said that five (that is, an odd number of) IGBT regions 11 are formed along the second direction. In FIG. 12, the first and second IGBT regions 11a and 11b, as well as the first and second FWD regions 12a and 12b, are formed in a concentric frame shape. Then, in FIG. 12, it can be said that four (that is, an even number of) IGBT regions 11 are formed along the second direction.

### Second Embodiment

The following describes a second embodiment of the present disclosure. The present embodiment differs from the first embodiment in that the widths of the FWD region 12 are changed. The other configurations of the present embodiment are similar to those of the first embodiment, and therefore a description of the similar configurations will be omitted.

In the first embodiment described, it has been assumed that the temperature of the semiconductor device 1 becomes highest when the IGBT elements are in the ON state than when the FWD elements are in the ON state. Therefore, a configuration in which the widths of the IGBT regions 11 are changed has been described. However, depending on the operating conditions and the impurity concentrations of each region, it is also conceivable that the temperature of the semiconductor device 1 becomes highest when the FWD elements are in the ON state. In the present embodiment, an example is described in which the temperature of the semiconductor device 1 becomes highest when the FWD elements are in the ON state.

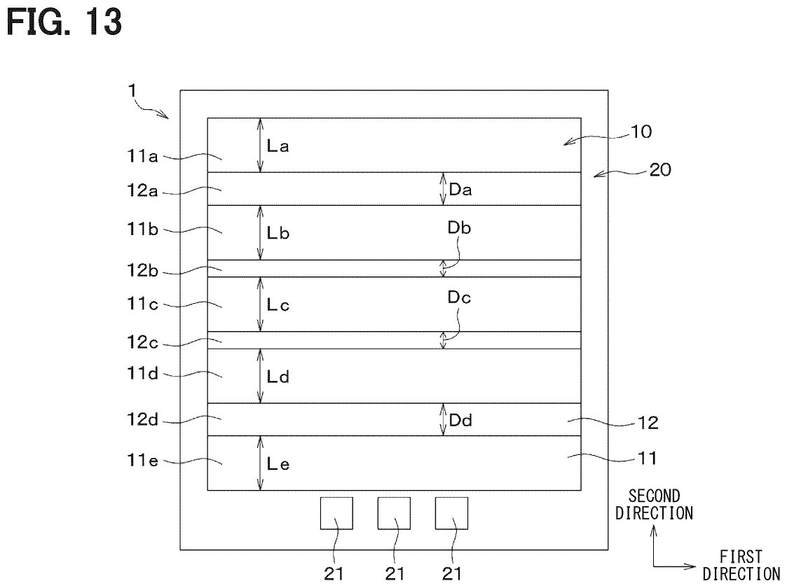

In the semiconductor device 1 of the present embodiment, as shown in FIG. 13, the widths La to Le of the first to fifth IGBT regions 11a to 11e are set to be equal to each other. Then, among the first to fifth FWD regions 12a to 12e, widths of regions located close to a central portion in the second direction are set to be narrower than widths of regions located close to end portions in the second direction. Specifically, in the present embodiment, the widths Db and Dc of the second and third FWD regions 12b and 12c are set to be narrower than the widths Da and Dd of the first and fourth FWD regions 12a and 12d.

The present inventors examined the maximum temperature of the semiconductor device 1 when the FWD elements are in the ON state, and results similar to those in FIG. 5 were obtained, although not specifically shown. That is, it was confirmed that, in the semiconductor device 1, within the range where the ratio of the maximum width to the minimum width of the FWD region 12 (hereinafter simply referred to as the FWD region width ratio) is less than 1.5, the maximum temperature of the semiconductor device 1 decreases sharply as the FWD region width ratio increases. Furthermore, it was confirmed that the maximum temperature of the semiconductor device 1 remains almost unchanged in the range where the FWD region width ratio is from 1.5 to 4.5. Therefore, it is preferable for the FWD region width ratio to be in the range of 1.5 to 4.5. It should be noted that the maximum temperature in the semiconductor device 1 of the present embodiment is the temperature of the second and third FWD regions 12b and 12c.

According to the present embodiment, the FWD region 12 is configured such that the widths of the regions located close to the central portion in the second direction are narrower than the widths of the regions located close to the end portions in the second direction. Therefore, compared to the case where the widths of the FWD regions 12 are set to be equal, it is possible to suppress the temperature of the FWD regions 12 located close to the central portion in the second direction from becoming excessively higher than the temperature of the FWD regions 12 located close to the end portions in the second direction.

In the present embodiment, among the first to fourth FWD regions 12a to 12d, the widths Db and Dc of the second and third FWD regions 12b and 12c, which are located close to the central portion in the second direction, are set to be the narrowest. Therefore, it is possible to suppress the temperature of the FWD regions 12 located close to the central portion in the second direction from becoming excessively high. In such a configuration, assuming that X FWD regions 12, where X is an even number of four or more, are arranged along the second direction, it can be said that the widths of the region positioned at the (X/2)th and the region positioned at the {(X/2)+1}th along the second direction are the narrowest.

In the present embodiment, by setting the FWD region width ratio to 1.5 to 4.5, the maximum temperature of the semiconductor device 1 can be sufficiently reduced.

### Modifications of Second Embodiment

Modifications of the second embodiment will be described below. In the second embodiment, although not specifically illustrated, the arrangement of the IGBT regions 11 and the FWD regions 12 may be appropriately modified, as in the modifications of the first embodiment.

For example, the FWD regions 12 may be arranged in an odd number along the second direction. In this case, when X FWD regions 12, where X is an odd number of three or more, are arranged along the second direction, it is sufficient to make the width of the region located at the {(X+1)/2}th position along the second direction the narrowest.

### Third Embodiment

The following describes a third embodiment of the present disclosure. The present embodiment is a combination of the first embodiment and the second embodiment. The other configurations of the present embodiment are similar to those of the first embodiment, and therefore a description of the similar configurations will be omitted.

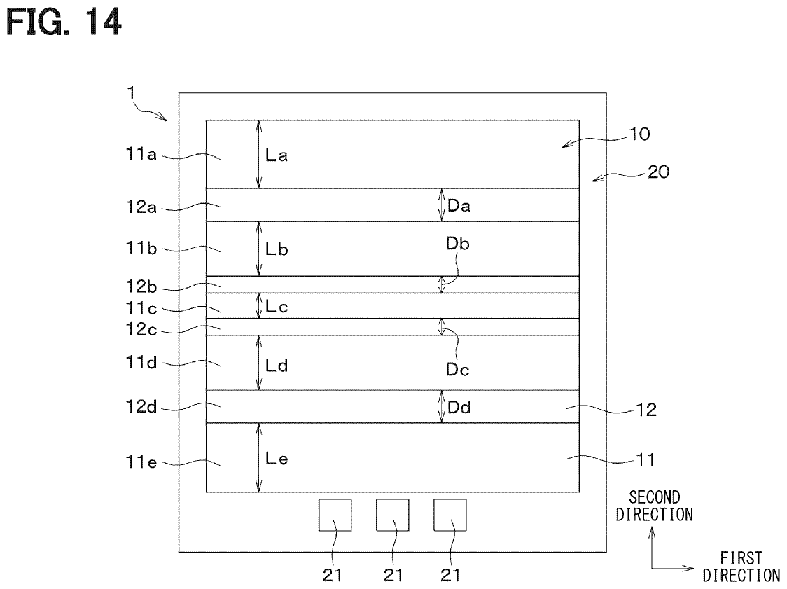

As shown in FIG. 14, the semiconductor device 1 of the present embodiment has a configuration that combines the first embodiment and the second embodiment. More specifically, the first to fifth IGBT regions 11a to 11e are formed such that the width Lc of the third IGBT region 11c is the narrowest, and the widths Lb and Ld of the second and fourth IGBT regions 11b and 11d and the widths La and Le of the first and fifth IGBT regions 11a and 11e become progressively wider in this order. In addition, the first to fourth FWD regions 12a to 12d are formed such that the widths Db and Dc of the second and third FWD regions 12b and 12c are set to be narrower than the widths Da and Dd of the first and fourth FWD regions 12a and 12d.

According to the present embodiment, effects similar to those of the first embodiment and the second embodiment can be obtained.

### Fourth Embodiment

The following describes a fourth embodiment. In the present embodiment, the width Le of the fifth IGBT region 11e is changed with respect to the first embodiment. The other configurations of the present embodiment are similar to those of the first embodiment, and therefore a description of the similar configurations will be omitted.

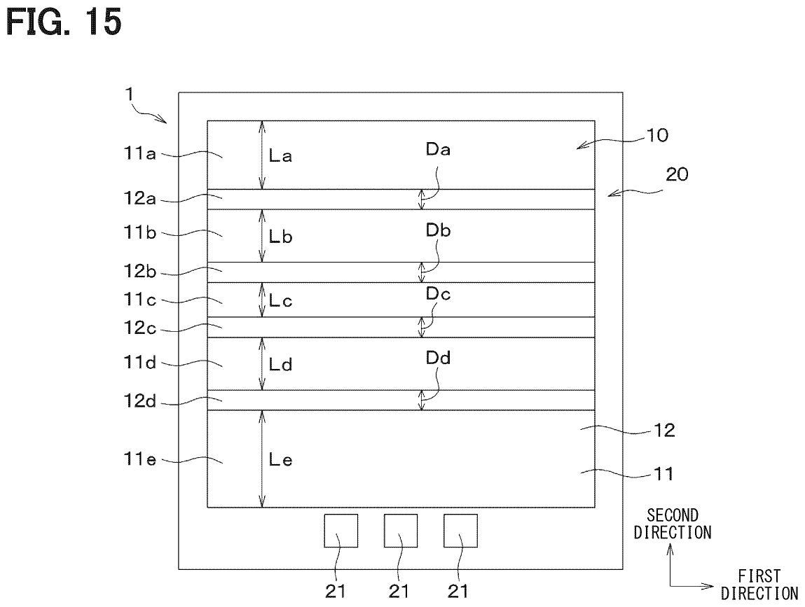

As shown in FIG. 15, the semiconductor device 1 of the present embodiment has the first to fifth IGBT regions 11a to 11e and the first to fourth FWD regions 12a to 12d, similarly to the first embodiment. The pad portions 21 are disposed in a portion of the outer peripheral region 20 on the side opposite to the fourth FWD region 12d, with the fifth IGBT region 11e interposed therebetween. In other words, the pad portions 21 are disposed in the vicinity of the fifth IGBT region 11e.

In the semiconductor device 1, when the IGBT elements are in the ON state, both the first IGBT region 11a and the fifth IGBT region 11e tend to have high heat dissipation capability because they can easily dissipate heat to the outer peripheral region 20. However, because the pad portions 21 are disposed in the vicinity of the fifth IGBT region 11e, a portion of the outer peripheral region 20 located close to the fifth IGBT region 11e is configured to be wider than a portion of the outer peripheral region 20 located close to the first IGBT region 11a. Therefore, when comparing the first IGBT region 11a and the fifth IGBT region 11e, the fifth IGBT region 11e exhibits higher heat dissipation than the first IGBT region 11a.

Therefore, in the present embodiment, the width Le of the fifth IGBT region 11e is made larger than the width La of the first IGBT region 11a. However, the width La of the first IGBT region 11a is made larger than the widths Lb to Ld of the second to fourth IGBT regions 11b to 11d.

According to the present embodiment, the width of the region of the IGBT region 11 located close to the central portion in the second direction is set to be narrower than the width of the regions located close to the end portions in the second direction. Therefore, effects similar to those of the first embodiment can be obtained.

In the present embodiment, the width Le of the fifth IGBT region 11e, which is located close to the pad portions 21, is made larger than the width La of the first IGBT region 11a. Therefore, it is possible to suppress the temperature of the first IGBT region 11a, which has lower heat dissipation than the fifth IGBT region 11e, from becoming higher than the temperature of the fifth IGBT region 11e.

### Fifth Embodiment

The following describes a fifth embodiment. The present embodiment is a combination of the second embodiment and the fourth embodiment. The other configurations of the present embodiment are similar to those of the second embodiment, and therefore a description of the similar configurations will not be repeated.

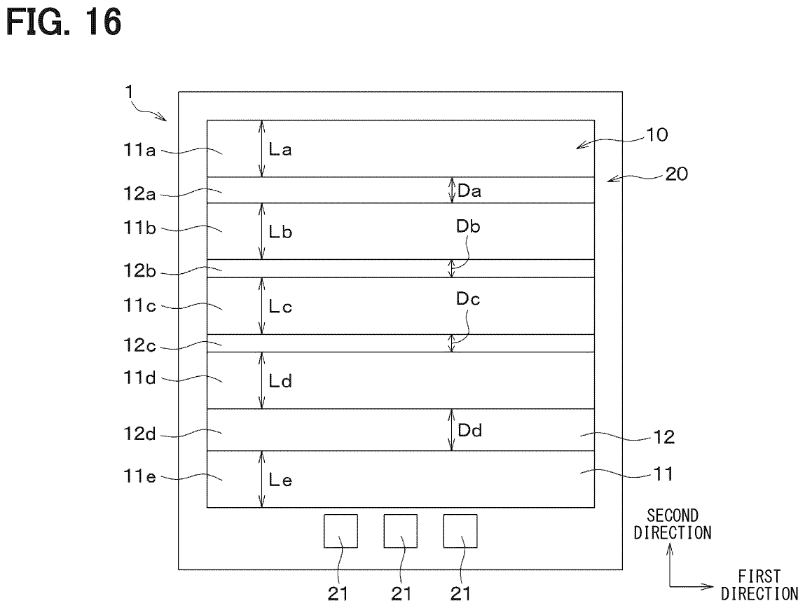

As shown in FIG. 16, the semiconductor device 1 of the present embodiment has the first to fifth IGBT regions 11a to 11e and the first to fourth FWD regions 12a to 12d similarly to the second embodiment. The pad portions 21 are disposed close to the fourth FWD region 12d. In this case, as in the fourth embodiment, when comparing the first FWD region 12a and the fourth FWD region 12d, the fourth FWD region 12d has higher heat dissipation than the first FWD region 12a.

Therefore, in the present embodiment, the width Dd of the fourth FWD region 12d is set to be wider than the width Da of the first FWD region 12a. However, the width Da of the first FWD region 12a is set to be wider than the widths Db and Dc of the second and third FWD regions 12b and 12c.

According to the present embodiment, the FWD region 12 is configured such that the widths of the regions located close to the central portion in the second direction are narrower than the widths of the regions located close to the end portions in the second direction. Therefore, effects similar to those of the second embodiment can be obtained.

In the present embodiment, the width Dd of the fourth FWD region 12d, which is located close to the pad portions 21, is set to be wider than the width Da of the first FWD region 12a. Therefore, it is possible to suppress the temperature of the first FWD region 12a, which has lower heat dissipation than the fourth FWD region 12d, from becoming higher than the temperature of the fourth FWD region 12d.

### Sixth Embodiment

The following describes a sixth embodiment. The present embodiment differs from the third embodiment in that FWD regions 12 are additionally disposed close to the pad portions 21 in the first direction. The other configurations of the present embodiment are similar to those of the third embodiment, and therefore a description of the similar configurations will not be repeated.

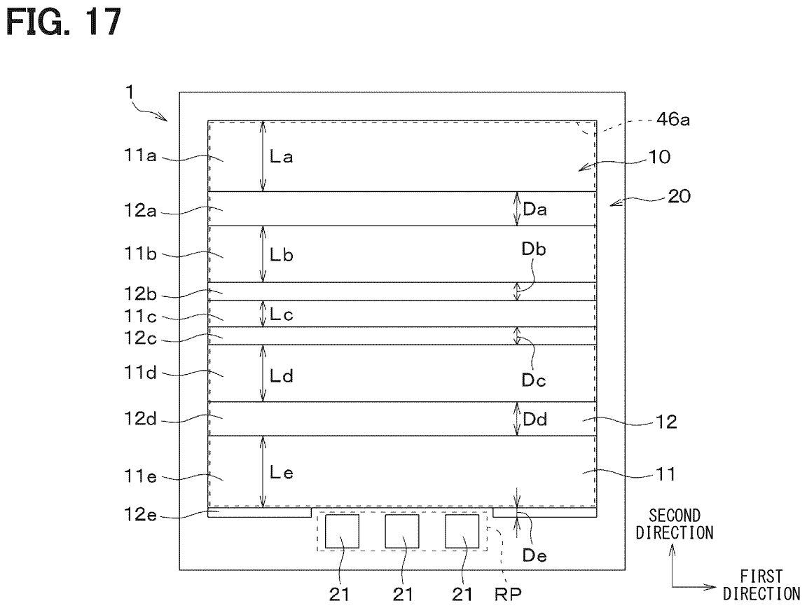

In the semiconductor device 1 of the present embodiment, as shown in FIG. 17, the FWD region 12 includes fifth FWD regions 12e, which are disposed on the side opposite to the fourth FWD region 12d with the fifth IGBT region 11e interposed therebetween. The fifth FWD regions 12e are disposed close to the pad portions 21 in the first direction.

In the present embodiment, two fifth FWD regions 12e having planar rectangular shapes are disposed so as to sandwich the pad portions 21 in the first direction. In other words, the fifth FWD regions 12e are arranged separated from each other in the first direction, and the pad portions 21 are disposed in a region where the fifth FWD regions 12e are divided. In other words, in the cell region 10, a region close to the pad portions 21 in the second direction is set to be the IGBT region 11, while the regions close to the pad portions 21 in the first direction are set to be the FWD regions 12. In other words, if a predetermined range including a region where the pad portions 21 are disposed is defined as an arrangement region RP, then in the cell region 10, the region close to the arrangement region RP in the second direction is set to be the IGBT region 11, and the regions close to the arrangement region RP in the first direction are set to be the FWD regions 12. It should be noted that, in the present embodiment, the fifth FWD regions 12e correspond to additional FWD regions.

In addition, in the semiconductor device 1 of the present embodiment, the opening portion of the contact hole 46a formed in the protective film 46 has a substantially rectangular planar shape, similar to that in the first embodiment. In other words, the contact hole 46a formed in the protective film 46 is formed so as to expose the first to fifth IGBT regions 11a to 11e and the first to fourth FWD regions 12a to 12d, and so as to cover the fifth FWD regions 12e.

In this way, by forming the opening portion of the contact hole 46a in a substantially rectangular planar shape, the following effects can be obtained compared to the case where the contact hole 46a is formed to also expose the fifth FWD regions 12e. That is, it becomes easier to control the spread of the second bonding member 202 (that is, solder) when assembling the semiconductor module. Therefore, variations in the bonding strength between the terminal 120 and the semiconductor device 1, as well as in the heat dissipation to the terminal 120, can be suppressed.

In this case, since the fifth FWD regions 12e are covered by the protective film 46, their heat dissipation tends to be lower compared to the first to fourth FWD regions 12a to 12d, which are exposed from the contact hole 46a of the protective film 46. Accordingly, in the present embodiment, the width De of the fifth FWD regions 12e is narrower than the widths Da to Dd of the first to fourth FWD regions 12a to 12d.

It should be noted that, in the present embodiment, the width of the region of the FWD region 12 located close to the center portion in the second direction within the area exposed from the contact hole 46a is set to be narrower than the width of the regions located close to the end portions in the second direction.

According to the present embodiment, since the widths of the IGBT region 11 and the FWD region 12 are the same as those in the third embodiment, effects similar to those of the third embodiment can be obtained.

In the present embodiment, the fifth FWD regions 12e are disposed at positions close to the pad portions 21 in the first direction. Therefore, since the FWD region 12 is disposed in a region that is the outer peripheral region 20 in the first embodiment, the thermal resistance of the FWD region 12 can be reduced.

In addition, in the outer peripheral region 20, the deep layer 44 that surrounds the cell region 10 and is connected to the base layer 32 is formed. Therefore, when the FWD elements are turned into the ON state, holes can also be supplied from the deep layer 44. In this case, if the FWD region 12 is disposed at a position close to the pad portions 21 in the second direction, the supply of holes may become excessive when the FWD elements are in the ON state, potentially resulting in a decrease in recovery tolerance. Therefore, in the present embodiment, the IGBT region 11 is disposed at the position close to the pad portion 21 in the second direction. As a result, it is possible to increase the active area of the FWD regions 12 while suppressing the decrease in recovery tolerance.

In the present embodiment, the width De of the fifth FWD regions 12e is narrower than the widths Da to Dd of the first to fourth FWD regions 12a to 12d. Therefore, it is possible to suppress an increase in the temperature of the fifth FWD regions 12e, which is covered by the protective film 46.

### Modifications of Sixth Embodiment

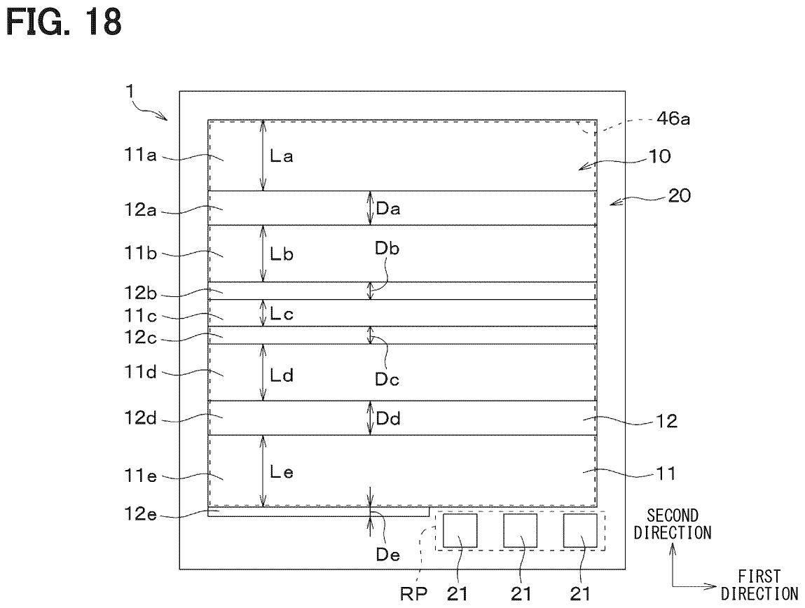

The following describes modifications of the sixth embodiment. In the sixth embodiment, as shown in FIG. 18, the pad portions 21 may be disposed close to the fifth IGBT region 11e in the second direction, at a position close to an end portion in the first direction of the cell region 10.

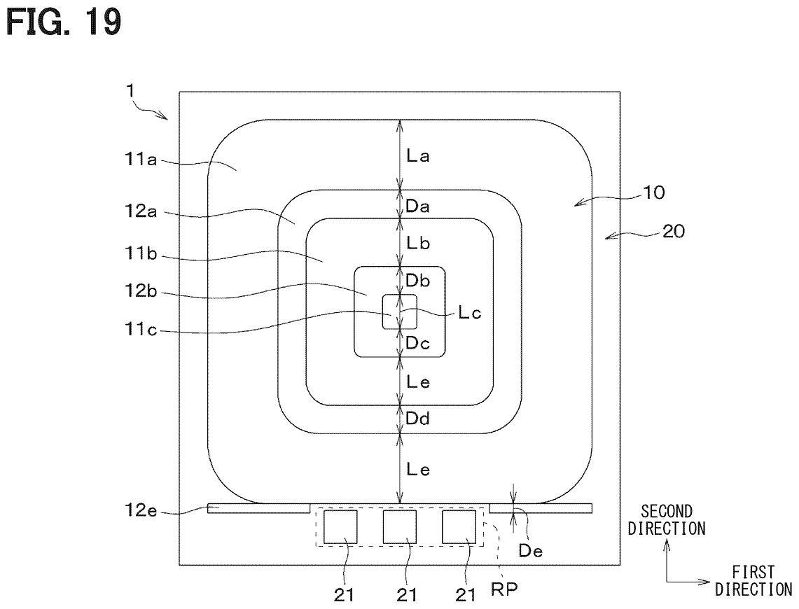

Furthermore, as shown in FIG. 19, the configuration in which the fifth FWD regions 12e are disposed can also be applied to a configuration in which the IGBT regions 11 and the FWD regions 12 are arranged in a concentric frame shape.

Furthermore, in the sixth embodiment, the contact hole 46a formed in the protective film 46 may be formed so as to expose the fifth FWD regions 12e. In this case, if the fifth FWD regions 12e have better heat dissipation than the first FWD region 12a due to being exposed from the protective film 46, the width De of the fifth FWD regions 12e may be made greater than the width Da of the first FWD region 12a.

Furthermore, in the sixth embodiment, the FWD region 12 may be disposed at a position close to the pad portions 21 in the second direction.

### Seventh Embodiment

The following describes a seventh embodiment. The present embodiment differs from the sixth embodiment in that the shapes of the fifth FWD regions 12e are changed. Other configurations are the same as those of the sixth embodiment, and therefore a description of the same configurations will be omitted.

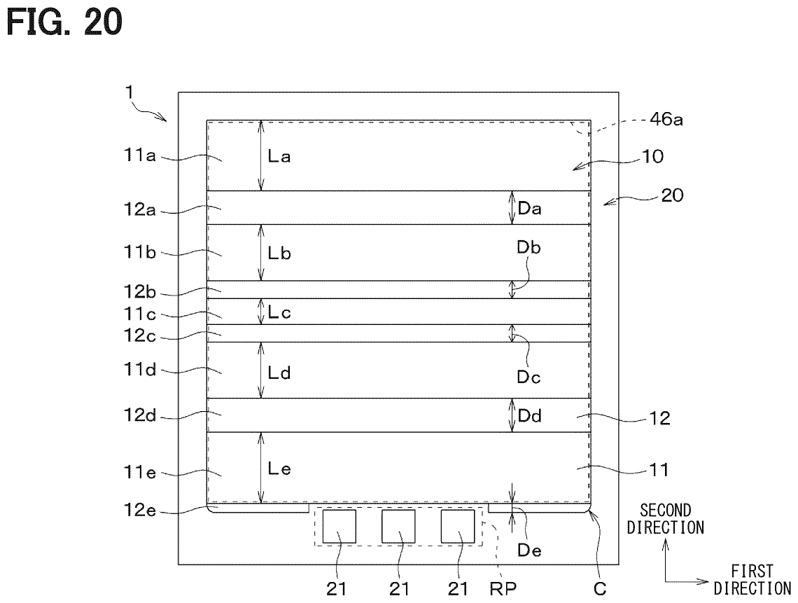

First, the deep layer 44 has a planar frame shape such as a rectangular frame with rounded corners or a circular frame. In this case, as in the sixth embodiment, if each of the fifth FWD regions 12e has a rectangular frame shape, the end of each of the fifth FWD regions 12e opposite to the pad portions 21 has a portion where the distance between the cathode layer 42 and the deep layer 44 is short and a portion where it is long. As a result, the electric field tends to concentrate at the portion where the distance between the cathode layer 42 and the deep layer 44 is short. Therefore, as shown in FIG. 20, each of the fifth FWD regions 12e of the present embodiment has a planar shape in which the end portion C in the first direction, opposite to the pad portions 21, is rounded so as to correspond to the shape of the deep layer 44. Such a configuration is achieved by adjusting the planar shape of the cathode layer 42.

According to the present embodiment, since the widths of the IGBT region 11 and the FWD region 12 are the same as those in the third embodiment, effects similar to those of the third embodiment can be obtained.

In the present embodiment, each of the fifth FWD regions 12e has a planar shape in which the end portion C in the first direction, opposite to the pad portions 21, is rounded so as to correspond to the corner portion of the deep layer 44. Therefore, variations in the distance between the cathode layer 42 and the deep layer 44 can be reduced, making it less likely for electric field concentration to occur.

### Other Embodiments

Although the present disclosure has been described in accordance with the embodiments, it is understood that the present disclosure is not limited to such embodiments or structures. The present disclosure encompasses various modifications and variations within the scope of equivalents. In addition, various combinations and forms, as well as other combinations or forms including more, less, or only a single element, also fall within the scope and spirit of the present disclosure.

For example, in each of the above-described embodiments, the example is described in which the first conductive type is N type and the second conductive type is P type. Alternatively, the first conductive type may be P type and the second conductive type may be N type.

In each of the above-described embodiments, the semiconductor device 1 may be of a planar type in which the gate electrodes 35 are disposed on the front surface 30a of the semiconductor substrate 30, instead of being a trench gate type.

Furthermore, in each of the above-described embodiments, the gate electrodes 35 of the FWD regions 12 do not necessarily have to be connected to the upper electrode 39. Additionally, in each of the above-described embodiments, the FWD regions 12 may be formed without a trench gate structure, and the emitter region 36 may also be omitted.

In addition, each of the above-described embodiments can be combined as appropriate. For example, by appropriately combining the above second embodiment, the width of the region of the FWD region 12 located close to the central portion in the second direction may be set to be narrower than the width of the regions located close to the end portions in the second direction. In this case, the widths of each IGBT region 11 may be set to be equal to each other. In addition, by appropriately combining the fourth embodiment, the width Le of the fifth IGBT region 11e located close to the pad portions 21 may be set to be narrower than the width La of the first IGBT region 11a. By appropriately combining the fifth embodiment, the width Dd of the fourth FWD region 12d located close to the pad portions 21 may be set to be narrower than the width Da of the first FWD region 12a.

What is claimed is:

1. A semiconductor device comprising:
a semiconductor substrate having a cell region and an outer peripheral region that surrounds the cell region;
a plurality of insulated gate bipolar transistor (IGBT) regions disposed in the cell region and each including an IGBT element; and
a plurality of freewheeling diode (FWD) regions disposed in the cell region and each including an FWD element, wherein
the plurality of IGBT regions and the plurality of FWD regions are alternately arranged along one direction in a planar direction of the semiconductor substrate,
the plurality of IGBT regions include three or more IGBT regions arranged along the one direction, a length along the one direction is defined as a width, and a width of one of the plurality of IGBT regions that is located close to a central portion in the one direction is narrower than a width of one of the plurality of IGBT regions that is located close to an end portion in the one direction,
the outer peripheral region includes a pad portion to be connected to an external terminal portion, and
a width of one of the plurality of IGBT regions that is closest to the pad portion is set to be wider than a width of one of the plurality of IGBT regions that is farthest from the pad portion.

2. A semiconductor device comprising:
a semiconductor substrate having a cell region and an outer peripheral region that surrounds the cell region;
a plurality of insulated gate bipolar transistor (IGBT) regions disposed in the cell region and each including an IGBT element; and
a plurality of freewheeling diode (FWD) regions disposed in the cell region and each including an FWD element, wherein
the plurality of IGBT regions and the plurality of FWD regions are alternately arranged along one direction in a planar direction of the semiconductor substrate,
the plurality of IGBT regions include three or more IGBT regions arranged along the one direction, a length along the one direction is defined as a width, and a width of one of the plurality of IGBT regions that is located close to a central portion in the one direction is narrower than a width of one of the plurality of IGBT regions that is located close to an end portion in the one direction, and
a ratio of the width of the one of the plurality of IGBT regions that is located close to the end portion in the one direction to the width of the one of the plurality of IGBT regions that is located close to the central portion in the one direction is set to be between 1.5 and 4.5.

3. The semiconductor device according to claim 1, wherein
a number of IGBT regions included in the plurality of IGBT regions is defined as X, where X is an odd number of three or more, and
a width of one of the plurality of IGBT regions that is located at an {(X+1)/2}th position along the one direction is narrowest among the plurality of IGBT regions.

4. The semiconductor device according to claim 1, wherein
a number of IGBT regions included in the plurality of IGBT regions is defined as X, where X is an even number of four or more, and
a width of one of the plurality of IGBT regions that is located at an (X/2)th position along the one direction and a width of one of the plurality of IGBT regions that is located at an {(X/2)+1}th position along the one direction are equal to each other and are narrowest among the plurality of IGBT regions.

5. The semiconductor device according to claim 1, wherein
the plurality of FWD regions include three or more FWD regions arranged along the one direction, and a width of one of the plurality of FWD regions that is located close to the central portion in the one direction is narrower than a width of one of the plurality of FWD regions that is located close to the end portion in the one direction.

6. A semiconductor device comprising:
a semiconductor substrate having a cell region and an outer peripheral region that surrounds the cell region;
a plurality of insulated gate bipolar transistor (IGBT) regions disposed in the cell region and each including an IGBT element; and
a plurality of freewheeling diode (FWD) regions disposed in the cell region and each including an FWD element, wherein
the plurality of IGBT regions and the plurality of FWD regions are alternately arranged along one direction in a planar direction of the semiconductor substrate,
the plurality of FWD regions include three or more FWD regions arranged along the one direction, a length along the one direction is defined as a width, and a width of one of the plurality of FWD regions that is located close to a central portion in the one direction is narrower than a width of one of the plurality of FWD regions that is located close to an end portion in the one direction,
a number of FWD regions included in the plurality of FWD regions is defined as X, where X is an odd number of three or more, and
a width of one of the plurality of FWD regions that is located at an {(X+1)/2}th position along the one direction is narrowest among the plurality of FWD regions.

7. The semiconductor device according to claim 6, wherein
the outer peripheral region includes a pad portion to be connected to an external terminal portion, and
a width of one of the plurality of FWD regions that is closest to the pad portion is set to be wider than a width of one of the plurality of FWD regions that is farthest from the pad portion.

8. A semiconductor device comprising:
a semiconductor substrate having a cell region and an outer peripheral region that surrounds the cell region;
a plurality of insulated gate bipolar transistor (IGBT) regions disposed in the cell region and each including an IGBT element; and
a plurality of freewheeling diode (FWD) regions disposed in the cell region and each including an FWD element, wherein
the plurality of IGBT regions and the plurality of FWD regions are alternately arranged along one direction in a planar direction of the semiconductor substrate,
the plurality of FWD regions include three or more FWD regions arranged along the one direction, a length along the one direction is defined as a width, and a width of one of the plurality of FWD regions that is located close to a central portion in the one direction is narrower than a width of one of the plurality of FWD regions that is located close to an end portion in the one direction,
the outer peripheral region includes a pad portion to be connected to an external terminal portion, and
a width of one of the plurality of FWD regions that is closest to the pad portion is set to be wider than a width of one of the plurality of FWD regions that is farthest from the pad portion.

9. The semiconductor device according to claim 8, wherein
a number of FWD regions included in the plurality of FWD regions is defined as X, where X is an even number of four or more, and
a width of one of the plurality of FWD regions that is located at an (X/2)th position along the one direction and a width of one of the plurality of FWD regions that is located at an {(X/2)+1}th position along the one direction are equal to each other and are narrowest among the plurality of FWD regions.

10. A semiconductor device comprising:
a semiconductor substrate having a cell region and an outer peripheral region that surrounds the cell region;
a plurality of insulated gate bipolar transistor (IGBT) regions disposed in the cell region and each including an IGBT element; and
a plurality of freewheeling diode (FWD) regions disposed in the cell region and each including an FWD element, wherein
the plurality of IGBT regions and the plurality of FWD regions are alternately arranged along one direction in a planar direction of the semiconductor substrate,
the plurality of FWD regions include three or more FWD regions arranged along the one direction, a length along the one direction is defined as a width, and a width of one of the plurality of FWD regions that is located close to a central portion in the one direction is narrower than a width of one of the plurality of FWD regions that is located close to an end portion in the one direction, and
a ratio of the width of the one of the plurality of FWD regions that is located close to the end portion in the one direction to the width of the one of the plurality of FWD regions that is located close to the central portion in the one direction is set to be between 1.5 and 4.5.

11. A semiconductor device comprising:
a semiconductor substrate having a cell region and an outer peripheral region that surrounds the cell region;
a plurality of insulated gate bipolar transistor (IGBT) regions disposed in the cell region and each including an IGBT element; and
a plurality of freewheeling diode (FWD) regions disposed in the cell region and each including an FWD element, wherein
the plurality of IGBT regions and the plurality of FWD regions are alternately arranged along one direction in a planar direction of the semiconductor substrate,
the plurality of FWD regions include three or more FWD regions arranged along the one direction, a length along the one direction is defined as a width, and a width of one of the plurality of FWD regions that is located close to a central portion in the one direction is narrower than a width of one of the plurality of FWD regions that is located close to an end portion in the one direction,
the outer peripheral region includes a pad portion to be connected to an external terminal portion,
the plurality of FWD region include an additional FWD region that is close to the pad portion in a direction intersecting the one direction, and
one of the plurality of IGBT region is disposed close to the pad portion in the one direction.

12. The semiconductor device according to claim 11, further comprising
a protective film having a contact hole that exposes the cell region, wherein
the additional FWD region is covered by the protective film, and
in a region exposed from the contact hole, the width of the one of the plurality of FWD regions that is located close to the central portion in the one direction is narrower than the width of one of the plurality of FWD regions that is located close to the end portion in the one direction, and
a width of the additional FWD region is narrower than the width of each of the plurality of FWD regions that are exposed from the contact hole.

13. The semiconductor device according to claim 11, wherein
the semiconductor substrate includes:
a drift layer of a first conductivity type;
a base layer of a second conductivity type disposed in a surface region of the drift layer in the cell region;
an emitter region of the first conductivity type disposed in a surface region of the base layer in the IGBT region so as to be separated from the drift layer, and having a higher impurity concentration than the drift layer;
a collector layer of the second conductivity type disposed on a side of the drift layer opposite to the base layer in the IGBT region; and
a cathode layer of the first conductivity type disposed on the side of the drift layer opposite to the base layer in the FWD region,
the outer peripheral region includes, at a boundary with the cell region, a deep layer of the second conductivity type that is connected to the base layer and surrounds the cell region,
the deep layer has a frame shape with rounded corners in plan view, and
the additional FWD region has an end portion that is located opposite to the pad portion in the direction intersecting the one direction, and the end portion has a rounded shape in plan view so as to correspond to one of the rounded corners of the deep layer.
